(19) United States
(12) Patent Application Publication
(10) Pub. No.: US 2024/0009773 A1
(43) Pub. Date: Jan. 11, 2024

(54) MANUFACTURING METHOD OF SUBSTRATE

(71) Applicant: DISCO CORPORATION, Tokyo (JP)

(72) Inventor: Asahi NOMOTO, Tokyo (JP)

(21) Appl. No.: 18/342,103

(22) Filed: Jun. 27, 2023

(30) Foreign Application Priority Data
Jul. 5, 2022 (JP) 2022-108098

(51) Int. Cl. B23K 26/57; B23K 26/067

(52) U.S. Cl. CPC B23K 26/57; B23K 26/0676; B23K 2103/56

(57) ABSTRACT

In the state in which a laser beam is split in such a manner that multiple focal points that line up along a first direction parallel to a specific crystal plane of a single-crystal material that configures an ingot are formed, the ingot and the multiple focal points are relatively moved along a second direction parallel to this specific crystal plane to form a separation layer. In this case, modified parts are formed with each of the multiple focal points being the center of the modified part. In addition, it becomes easier for cracks to extend from these modified parts along the specific crystal plane. Thus, in this case, the cracks formed inside the ingot can be made longer without setting the output power of the laser beam higher. As a result, it becomes possible to improve the throughput in manufacturing a substrate from the ingot.

### BACKGROUND OF THE INVENTION

### Field of the Invention

The present invention relates to a manufacturing method of a substrate by which the substrate is manufactured from an ingot composed of a single-crystal material.

### Description of the Related Art

In general, chips of a semiconductor device are manufactured by using a circular disc-shaped substrate composed of a single-crystal material such as silicon, silicon carbide, gallium nitride, lithium tantalate (LT), or lithium niobate (LN). This substrate is cut out from an ingot with a circular column shape by using a wire saw, for example (for example, refer to Japanese Patent Laid-open No. 2000-94221).

However, the cutting allowance taken when the substrate is cut out from the ingot by using the wire saw is approximately 300 μm, which is relatively large. Furthermore, minute recesses and projections are formed in a surface of the substrate thus cut out, and this substrate bends totally (warpage occurs in the substrate). Thus, when chips are manufactured by using this substrate, the surface of the substrate needs to be planarized through executing lapping, etching, and/or polishing for the surface.

In this case, the amount of semiconductor material used as the substrates finally is approximately ⅔ of the total amount of ingot. That is, approximately ⅓ of the total amount of ingot is discarded in the cutting-out of the substrates from the ingot and the planarization of surfaces of the substrates. Thus, the productivity becomes low in the case of manufacturing the substrates by using the wire saw as above.

In view of this point, a method has been proposed in which separation layers including modified parts and cracks that extend from the modified parts are formed inside an ingot by irradiating the ingot with a laser beam with such a wavelength as to be transmitted through a single-crystal material from the front surface side and thereafter a substrate is split off from the ingot with use of these separation layers as the point of origin (for example, refer to Japanese Patent Laid-open No. 2016-111143). When a substrate is manufactured from an ingot by using this method, the productivity of the substrate can be improved compared with the case in which the substrate is manufactured from the ingot by using the wire saw.

### SUMMARY OF THE INVENTION

This method is a method of generally-called single wafer processing in which the substrates are manufactured from the ingot one by one. On the other hand, in the case of manufacturing the substrates from the ingot by using the wire saw, it is possible to simultaneously manufacture multiple substrates from the ingot. Thus, there is a possibility that the throughput lowers in the case of manufacturing the substrate from the ingot by using the laser beam.

To improve the throughput in manufacturing the substrate from the ingot by using the laser beam, for example, the output power of the laser beam with which the ingot is irradiated can be set higher. This makes the cracks that extend from the modified parts formed inside the ingot longer. As a result, the length of time necessary for the formation of the separation layers that become the point of origin when the substrate is split off from the ingot can be made shorter.

However, to set the output power of the laser beam higher, the size of a laser oscillator that generates the laser beam needs to be made larger. Thus, in this case, the size of a laser processing apparatus including the laser oscillator becomes larger, and the cost thereof becomes higher. Moreover, in this case, there is a possibility that a component (for example, collecting lens or the like) included in an optical system for irradiating the ingot with the laser beam is damaged and an optical characteristic thereof deteriorates.

In view of this point, an object of the present invention is to provide a manufacturing method of a substrate that can improve the throughput in manufacturing a substrate from an ingot by using a laser beam, without setting the output power of the laser beam higher.

In accordance with an aspect of the present invention, there is provided a manufacturing method of a substrate by which the substrate is manufactured from an ingot composed of a single-crystal material. The manufacturing method includes a separation layer forming step of forming separation layers including modified parts and cracks that extend from the modified parts inside the ingot by executing irradiation with a laser beam with such a wavelength as to be transmitted through the single-crystal material from the side of a front surface and a splitting-off step of splitting off the substrate from the ingot with use of the separation layers as a point of origin. In the separation layer forming step, the separation layers are formed by relatively moving the ingot and a plurality of focal points along a second direction parallel to each of the front surface and a specific crystal plane of the single-crystal material in a state in which the laser beam is split in such a manner that the plurality of focal points that line up along a first direction that is non-parallel to the front surface and is parallel to the specific crystal plane are formed.

In the present invention, in the state in which the laser beam is split in such a manner that the multiple focal points that line up along the first direction parallel to the specific crystal plane of the single-crystal material that configures the ingot are formed, the ingot and the multiple focal points are relatively moved along the second direction parallel to this specific crystal plane to cause the separation layer to be formed.

In this case, the modified parts are formed with each of the multiple focal points being the center of the modified part. In addition, it becomes easier for the cracks to extend from these modified parts along the specific crystal plane. Moreover, the cracks that extend along the specific crystal plane are likely to become longer than cracks that disorderly extend.

Thus, in this case, the cracks formed inside the ingot can be made longer without setting the output power of the laser beam higher. As a result, in the present invention, it becomes possible to improve the throughput in manufacturing the substrate from the ingot.

The above and other objects, features and advantageous effects of the present invention and the manner of realizing them will become more apparent, and the invention itself will best be understood from a study of the following description and appended claim with reference to the attached drawings showing a preferred embodiment of the invention.

### BRIEF DESCRIPTION OF THE DRAWINGS

FIG. 1 is a perspective view schematically illustrating one example of an ingot used for manufacturing of a substrate;

FIG. 2 is a top view schematically illustrating the ingot illustrated in FIG. 1;

FIG. 3 is a side view schematically illustrating the ingot illustrated in FIG. 1;

FIG. 4 is a flowchart schematically illustrating one example of a manufacturing method of a substrate by which the substrate is manufactured from the ingot;

FIG. 5 is a diagram schematically illustrating one example of a laser processing apparatus for executing a separation layer forming step (S1) illustrated in FIG. 4;

FIG. 6 is a top view schematically illustrating the state in which the ingot is held by a holding table of the laser processing apparatus;

FIG. 7 is a flowchart schematically illustrating one example of the separation layer forming step (S1) illustrated in FIG. 4;

FIG. 8 is a top view schematically illustrating the state of a laser beam irradiation step (S11) illustrated in FIG. 7;

FIG. 9 is a sectional view schematically illustrating the ingot irradiated with a laser beam in the laser beam irradiation step (S11) illustrated in FIG. 7;

FIG. 10A is a partially sectional side view schematically illustrating one example of a splitting-off step (S2) illustrated in FIG. 4;

FIG. 10B is a partially sectional side view schematically illustrating the one example of the splitting-off step (S2) illustrated in FIG. 4;

FIG. 11A is a partially sectional side view schematically illustrating another example of the splitting-off step (S2) illustrated in FIG. 4; and

FIG. 11B is a partially sectional side view schematically illustrating the other example of the splitting-off step (S2) illustrated in FIG. 4.

### DETAILED DESCRIPTION OF THE PREFERRED EMBODIMENT

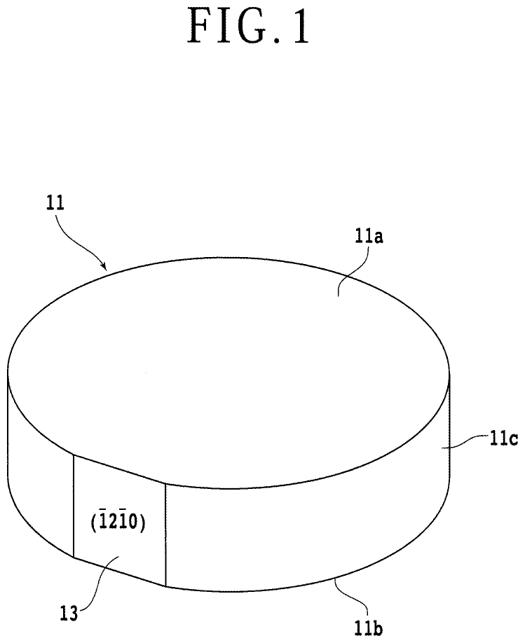

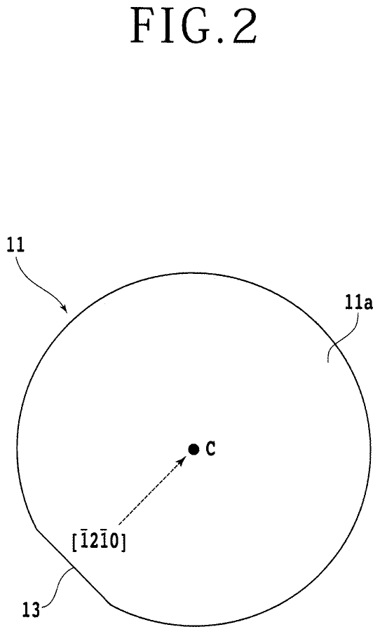

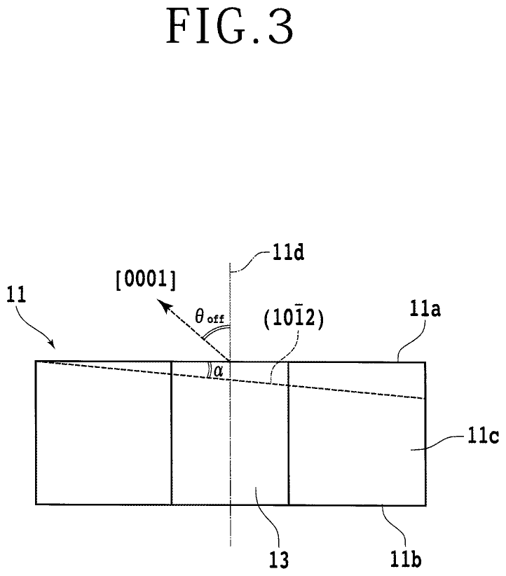

An embodiment of the present invention will be described with reference to the accompanying drawings. FIG. 1 is a perspective view schematically illustrating one example of an ingot used for manufacturing of a substrate. Furthermore, FIG. 2 is a top view schematically illustrating the ingot illustrated in FIG. 1. Moreover, FIG. 3 is side view schematically illustrating the ingot illustrated in FIG. 1.

An ingot 11 illustrated in FIGS. 1 to 3 is composed of a single-crystal material of the hexagonal system. Furthermore, crystal planes of this single-crystal material are also illustrated in FIG. 1 and FIG. 3, and crystal orientations of this single-crystal material are also illustrated in FIG. 2 and FIG. 3.

For example, the ingot 11 is a circular columnar LT ingot having a front surface 11a and a back surface 11b parallel to each other. In addition, an orientation flat 13 is formed in a side surface 11c of the ingot 11.

Moreover, a center C of the ingot 11 is located in the crystal orientation [−12-10] as viewed from the orientation flat 13. That is, the crystal plane (−12-10) is exposed in the orientation flat 13.

Furthermore, the c-axis (crystal orientation [0001]) of the single-crystal material that configures the ingot 11 is inclined with respect to a perpendicular line 11d to the front surface 11a and the back surface lib. For example, the angle (off-angle) Goff formed by the c-axis and the perpendicular line 11d is approximately 48°.

Here, the angle formed by the crystal plane (10-12), which is a crystal plane parallel to the crystal orientation [−12-10], and the c-plane (crystal plane (0001)) is approximately 57°. Thus, an angle α formed by the crystal plane (10-12) and the front surface 11a or the back surface 11b of the ingot 11 is approximately 9°.

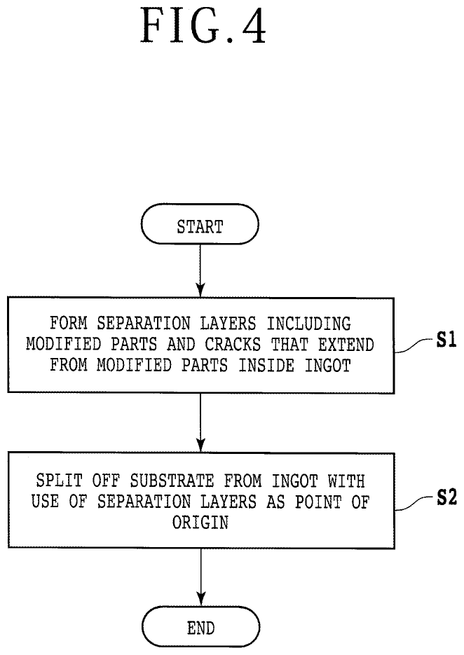

FIG. 4 is a flowchart schematically illustrating one example of a manufacturing method of a substrate by which the substrate is manufactured from the ingot 11. In this method, first, separation layers including modified parts and cracks that extend from the modified parts are formed inside the ingot 11 (separation layer forming step: S1).

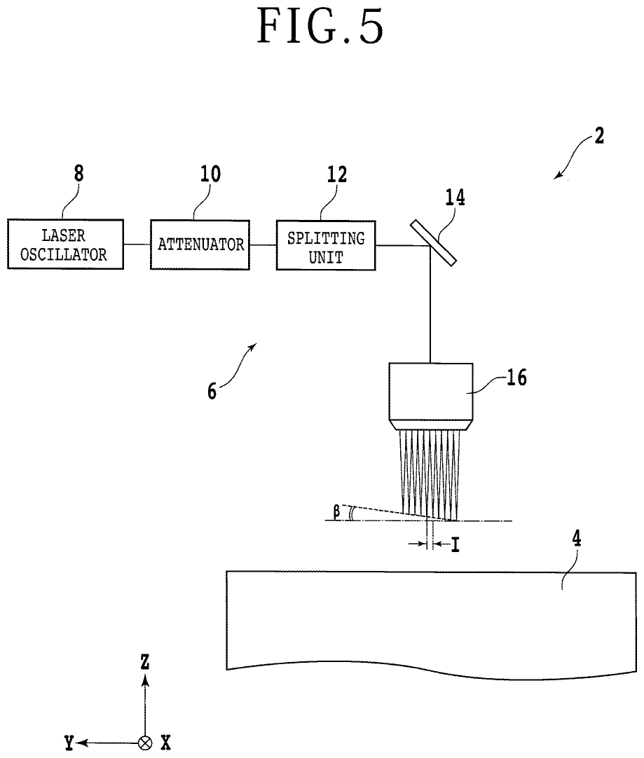

FIG. 5 is a diagram schematically illustrating one example of a laser processing apparatus for executing the separation layer forming step (S1). An X-axis direction and a Y-axis direction illustrated in FIG. 5 are directions orthogonal to each other on the horizontal plane. Moreover, a Z-axis direction is the direction (vertical direction) orthogonal to each of the X-axis direction and the Y-axis direction.

A laser processing apparatus 2 illustrated in FIG. 5 has a holding table 4 with a circular disc shape. The holding table 4 has a circular upper surface (holding surface) parallel to the X-axis direction and the Y-axis direction, for example. Furthermore, the holding table 4 has a circular disc-shaped porous plate (not illustrated) having an upper surface exposed in this holding surface.

Moreover, this porous plate communicates with a suction source (not illustrated) such as an ejector through a flow path formed inside the holding table 4, and so forth. Furthermore, when this suction source operates, a suction force acts on a space in the vicinity of the holding surface of the holding table 4. This can hold the ingot 11 placed on the holding surface by the holding table 4, for example.

Moreover, a laser beam irradiation unit 6 is disposed over the holding table 4. The laser beam irradiation unit 6 has a laser oscillator 8. For example, this laser oscillator 8 has neodymium:yttrium-aluminum-garnet (Nd:YAG) or the like as a laser medium.

Furthermore, the laser oscillator 8 emits a laser beam LB with such a wavelength as to be transmitted through the single-crystal material (LT) that configures the ingot 11 (for example, 1064 nm). The laser beam LB is pulse-oscillated, and the frequency thereof is, for example, 20 to 80 kHz, typically 50 kHz, and the pulse time width thereof is, for example, 5 to 30 ps, typically 15 ps.

The laser beam LB is adjusted in an attenuator 10 in such a manner that the average of the output power (power) thereof becomes, for example, 0.5 to 2.0 W, typically 1.3 W, and thereafter is supplied to a splitting unit 12. For example, the splitting unit 12 has a spatial light modulator including a liquid crystal phase control element referred to as liquid crystal on silicon (LCoS) and/or a diffractive optical element (DOE), and so forth.

Moreover, the splitting unit 12 splits the laser beam LB in such a manner that the laser beam LB with which the holding surface side of the holding table 4 is irradiated from an irradiation head 16 to be described later forms multiple (for example, 4 to 20, typically 10) focal points that line up along a predetermined direction orthogonal to the X-axis direction.

Specifically, the splitting unit 12 splits the laser beam LB in such a manner that an interval I in the Y-axis direction between a pair of adjacent focal points in the multiple focal points becomes, for example, 5 to 30 μm, typically 12.5 μm, and an angle β formed by the predetermined direction and the plane parallel to the X-axis direction and the Y-axis direction (XY-plane) becomes equal to the angle α illustrated in FIG. 3.

The laser beam LB split in the splitting unit 12 is reflected by a mirror 14 and is guided to the irradiation head 16. A collecting lens (not illustrated) that focuses the laser beam LB and so forth are housed in the irradiation head 16.

The numerical aperture (NA) of this collecting lens is, for example, 0.75. Furthermore, the laser beam LB focused by this collecting lens is emitted toward the holding surface of the holding table 4, to put it simply, directly below, with a central region of the lower surface of the irradiation head 16 being an emission region.

Moreover, the irradiation head 16 of the laser beam irradiation unit 6 and an optical system (for example, mirror 14 and so forth) for guiding the laser beam LB to the irradiation head 16 are coupled to a movement mechanism (not illustrated). This movement mechanism includes a ball screw, a motor, and so forth, for example. Furthermore, when this movement mechanism operates, the emission region of the laser beam LB moves along the X-axis direction, the Y-axis direction, and/or the Z-axis direction.

Moreover, in the laser processing apparatus 2, by operating this movement mechanism, the position (coordinates) in the X-axis direction, the Y-axis direction, and the Z-axis direction regarding the multiple focal points on each of which the laser beam LB with which the holding surface side of the holding table 4 is irradiated from the irradiation head 16 is focused can be adjusted.

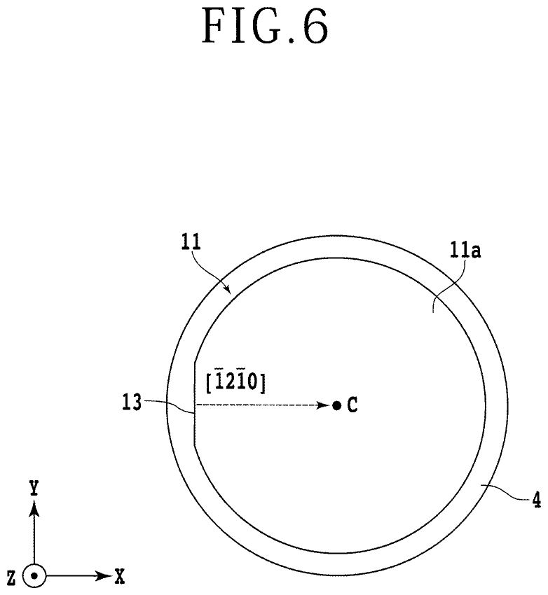

When the ingot 11 is carried in to the laser processing apparatus 2, the ingot 11 is held by the holding table 4 in the state in which the front surface 11a is oriented upward. FIG. 6 is a top view schematically illustrating the state in which the ingot 11 is held by the holding table 4 of the laser processing apparatus 2.

Specifically, first, the ingot 11 is placed on the holding table 4 in such a manner that the direction from the orientation flat 13 toward the center C of the ingot 11 (crystal orientation [−12-10]) corresponds with the X-axis direction and the center C overlaps with the center of the holding surface of the holding table 4.

Subsequently, the suction source communicating with the porous plate exposed in the holding surface of the holding table 4 is operated. This causes the ingot 11 to be held by the holding table 4 in the state in which each of the front surface 11a and the back surface 11b of the ingot 11 is parallel to the XY-plane.

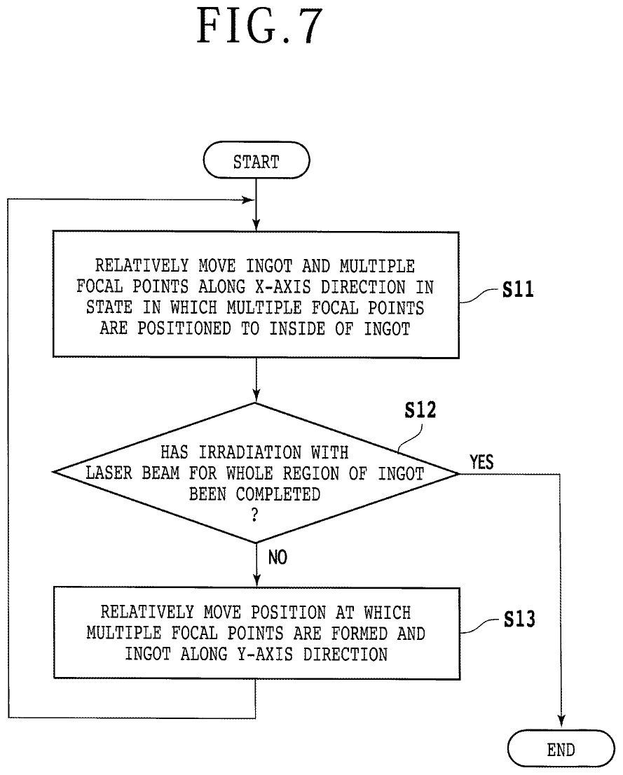

Furthermore, after the ingot 11 is held by the holding table 4, the separation layer forming step (S1) is executed. FIG. 7 is a flowchart schematically illustrating one example of the separation layer forming step (S1).

In this separation layer forming step (S1), first, the irradiation head 16 is moved to cause a region located at one end of the ingot 11 in the Y-axis direction to be positioned in the X-axis direction as viewed from the irradiation head 16 in plan view.

Next, the irradiation head 16 is raised and lowered to cause the multiple focal points to be positioned to the inside of the ingot 11 when the ingot 11 is irradiated with the laser beam LB. For example, the irradiation head 16 is raised and lowered to cause the average of the depth of the multiple focal points from the front surface 11a of the ingot 11 to become, for example, 120 to 200 μm, typically 160 μm.

Subsequently, in the state in which the multiple focal points on each of which the laser beam LB is focused are positioned to the inside of the ingot 11, the ingot 11 and the multiple focal points are relatively moved along the X-axis direction (crystal orientation [−12-10]) (laser beam irradiation step: S11).

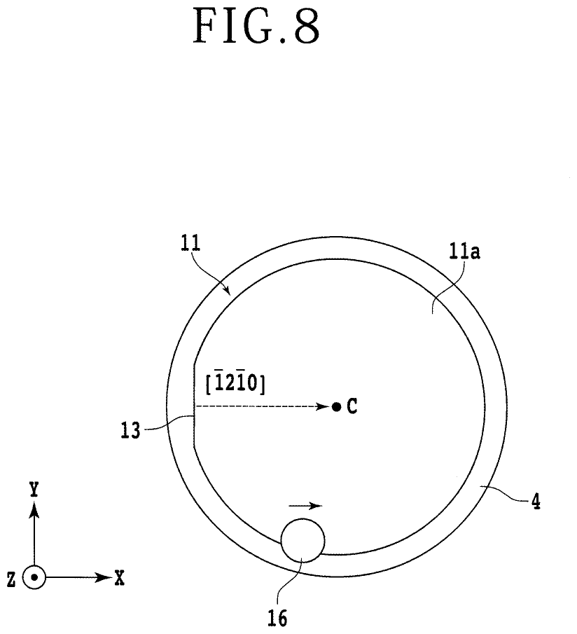

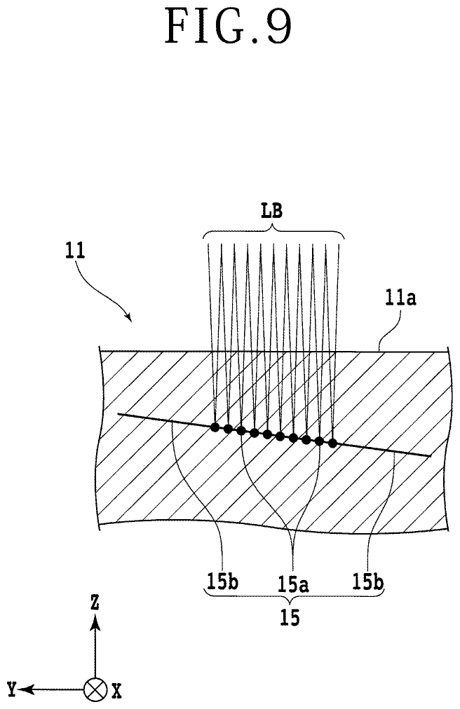

FIG. 8 is a top view schematically illustrating the state of the laser beam irradiation step (S11). FIG. 9 is a sectional view schematically illustrating the ingot 11 irradiated with the laser beam LB in the laser beam irradiation step (S11).

Specifically, in this laser beam irradiation step (S11), while the laser beam LB is emitted from the irradiation head 16 toward the holding table 4, the irradiation head 16 is moved to pass from one end to the other end of the ingot 11 in the X-axis direction (crystal orientation [−12-10]) in plan view (see FIG. 8).

Due to this, inside the ingot 11, a modified part 15a arising from disordering of the crystal structure is formed with each of the multiple focal points being the center of the modified part 15a (see FIG. 9). In addition, when the modified parts 15a are formed inside the ingot 11, the volume of the ingot 11 expands, and an internal stress is generated in the ingot 11.

Moreover, cracks 15b extend from the modified parts 15a to alleviate this internal stress inside the ingot 11. As a result, a separation layer 15 including the multiple modified parts 15a and the cracks 15b that develop from each of the multiple modified parts 15a is formed inside the ingot 11.

Here, each of the front surface 11a and the back surface 11b of the ingot 11 is parallel to the XY-plane and the angle β formed by the above-described predetermined direction (direction along which the multiple focal points on each of which the laser beam LB is focused line up) and the XY-plane is equal to the angle α illustrated in FIG. 3. Thus, the multiple focal points line up along the crystal plane (10-12) of the single-crystal material that configures the ingot 11.

In this case, the multiple modified parts 15a formed in association with the irradiation with the laser beam LB also line up along the crystal plane (10-12) of the single-crystal material. In addition, the cracks 15b that extend from each of the multiple modified parts 15a are also likely to become long along the crystal plane (10-12).

Furthermore, in the situation in which irradiation with the laser beam LB for the whole region of the ingot 11 (all of regions from the region located at one end in the Y-axis direction to the region located at the other end) has not been completed (step (S12): NO), the position at which the multiple focal points are formed and the ingot 11 are relatively moved along the Y-axis direction (indexing feed step: S13).

In this indexing feed step (S13), for example, the irradiation head 16 is moved along the Y-axis direction by, for example, 300 to 800 μm, typically 500 μm, in such a manner that the irradiation head 16 is brought closer to the other end of the ingot 11.

Next, the above-described laser beam irradiation step (S11) is executed again. That is, while the laser beam LB is emitted from the irradiation head 16 toward the holding table 4, the irradiation head 16 is moved to pass from one end to the other end of the ingot 11 in the X-axis direction (crystal orientation [−12-10]) in plan view.

Moreover, the indexing feed step (S13) and the laser beam irradiation step (S11) are alternately executed repeatedly until the separation layers 15 are formed in the whole region of the ingot 11. Then, when the irradiation with the laser beam LB for the whole region of the ingot 11 has been completed (step (S12): YES), the separation layer forming step (S1) illustrated in FIG. 4 is completed.

In the separation layer forming step (S1) of the present invention, the above-described irradiation with the laser beam LB for the whole region of the ingot 11 may be repeated multiple times (for example, four times). In this case, it is possible to increase the density of the modified parts 15a and the cracks 15b formed inside the ingot 11 and/or make the cracks 15b longer.

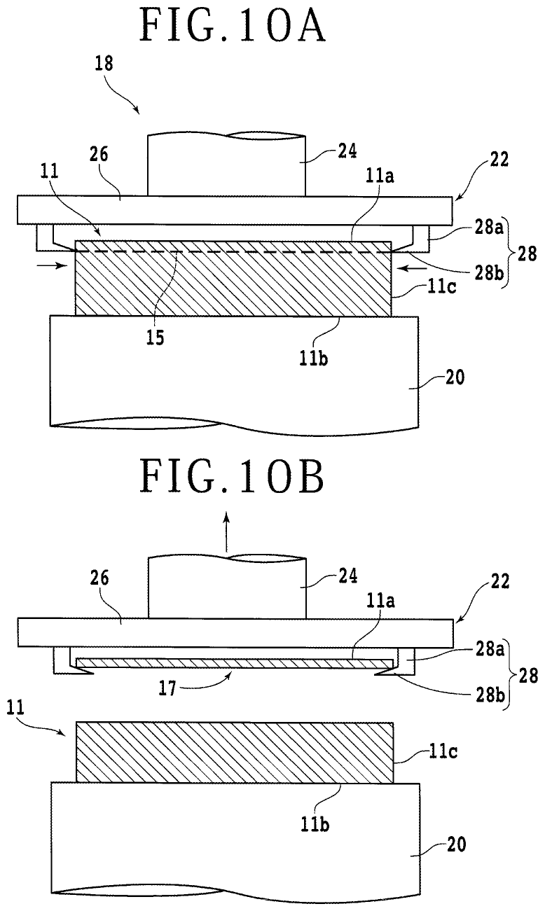

Furthermore, after the separation layer forming step (S1) is completed, a substrate is split off from the ingot 11 with use of the separation layers 15 as the point of origin (splitting-off step: S2). Each of FIG. 10A and FIG. 10B is a partially sectional side view schematically illustrating one example of the splitting-off step (S2) illustrated in FIG. 4.

For example, this splitting-off step (S2) is executed in a splitting-off apparatus 18 illustrated in FIG. 10A and FIG. 10B. The splitting-off apparatus 18 has a holding table 20 that holds the ingot 11 in which the separation layers 15 have been formed. The holding table 20 has a circular upper surface (holding surface) and a porous plate (not illustrated) is exposed in this holding surface.

Moreover, this porous plate communicates with a suction source (not illustrated) such as an ejector through a flow path made inside the holding table 20, and so forth. Furthermore, when this suction source operates, a suction force acts on a space in the vicinity of the holding surface of the holding table 20. This can hold the ingot 11 placed on the holding surface by the holding table 20, for example.

Moreover, a splitting-off unit 22 is disposed over the holding table 20. The splitting-off unit 22 has a support component 24 with a circular column shape. To an upper part of the support component 24, a raising-lowering mechanism (not illustrated) of a ball screw system and a rotational drive source such as a motor are coupled, for example.

Furthermore, the support component 24 rises and lowers by operating this raising-lowering mechanism. In addition, by operating this rotational drive source, the support component 24 rotates with a straight line that passes through the center of the support component 24 and is along the direction perpendicular to the holding surface of the holding table 20 being the rotation axis.

Moreover, a lower end part of the support component 24 is fixed to the center of an upper part of a base 26 with a circular disc shape. Furthermore, on the lower side of an outer circumferential region of the base 26, multiple movable components 28 are disposed at substantially equal intervals along the circumferential direction of the base 26. These movable components 28 each have a plate-shaped drooping part 28a extending downward from the lower surface of the base 26.

Upper end parts of these drooping parts 28a are coupled to an actuator such as an air cylinder incorporated in the base 26 and the movable components 28 move along the radial direction of the base 26 by operating this actuator. Moreover, plate-shaped wedge parts 28b that extend toward the center of the base 26 and in which the thickness becomes thinner toward the tip are disposed on the inner side surfaces of lower end parts of these drooping parts 28a.

When the ingot 11 is carried in to the splitting-off apparatus 18, the ingot 11 is held by the holding table 20 in the state in which the front surface 11a is oriented upward. Specifically, first, the ingot 11 is placed on the holding table 20 in such a manner that the center of the back surface 11b of the ingot 11 is made to correspond with the center of the holding surface of the holding table 20.

Subsequently, the suction source communicating with the porous plate exposed in this holding surface is operated. This causes the ingot 11 to be held by the holding table 20. Furthermore, after the ingot 11 is held by the holding table 20, the splitting-off step (S2) is executed.

Specifically, first, the actuator is operated to position each of the multiple movable components 28 to the outside in the radial direction of the base 26. Subsequently, the raising-lowering mechanism is operated to position the tip of the wedge part 28b of each of the multiple movable components 28 to a height corresponding to the separation layers 15 formed inside the ingot 11.

Next, the actuator is operated to cause the wedge parts 28b to be driven into the side surface 11c of the ingot 11 (see FIG. 10A). Subsequently, the rotational drive source is operated to rotate the wedge parts 28b driven into the side surface 11c of the ingot 11. Next, the raising-lowering mechanism is operated to raise the wedge parts 28b (see FIG. 10B).

By raising the wedge parts 28b after driving the wedge parts 28b into the side surface 11c of the ingot 11 and rotating them as above, the cracks 15b included in the respective separation layers 15 further extend to connect the adjacent separation layers 15. As a result, the side of the front surface 11a and the side of the back surface 11b of the ingot 11 are split off. That is, a substrate 17 is manufactured from the ingot 11 with use of the separation layers 15 as the point of origin.

The wedge parts 28b do not need to be rotated in the case in which the side of the front surface 11a and the side of the back surface 11b of the ingot 11 are split off at the timing when the wedge parts 28b are driven into the side surface 11c of the ingot 11. Furthermore, the wedge parts 28b that rotate may be driven into the side surface 11c of the ingot 11 through simultaneously operating the actuator and the rotational drive source.

In the method illustrated in FIG. 4, in the state in which the laser beam LB is split in such a manner that multiple focal points that line up along a direction parallel to the crystal plane (10-12) of the single-crystal material that configures the ingot 11 (first direction) are formed, the ingot 11 and the multiple focal points are relatively moved along a direction parallel to the crystal plane (10-12), specifically, the crystal orientation [−12-10] (second direction), to cause the separation layer 15 to be formed.

In this case, the modified parts 15a are formed with each of the multiple focal points being the center of the modified part 15a. In addition, it becomes easier for the cracks 15b to extend from these modified parts 15a along the crystal plane (10-12). Moreover, the cracks 15b that extend along the crystal plane (10-12) are likely to become longer than cracks that disorderly extend.

Thus, in this case, the cracks 15b formed inside the ingot 11 can be made longer without setting the output power of the laser beam LB higher. As a result, in the method illustrated in FIG. 4, it becomes possible to improve the throughput in manufacturing the substrate 17 from the ingot 11.

The above-described manufacturing method of the substrate is one aspect of the present invention and the present invention is not limited to the above-described method. For example, the ingot used in order to manufacture the substrate in the present invention is not limited to the ingot 11 illustrated in FIGS. 1 to 3 and so forth.

Specifically, in the present invention, a substrate may be manufactured from an ingot in which a notch is formed in a side surface. Alternatively, in the present invention, a substrate may be manufactured from an ingot in which neither an orientation flat nor a notch is formed in a side surface. In addition, in the present invention, a substrate may be manufactured from a circular columnar ingot composed of a single-crystal material other than LT.

Furthermore, the structure of the laser processing apparatus used in the separation layer forming step (S1) of the present invention is not limited to the structure of the above-described laser processing apparatus 2. For example, the separation layer forming step (S1) may be executed by using a laser processing apparatus equipped with a movement mechanism that moves the holding table 4 along each of the X-axis direction, the Y-axis direction, and/or the Z-axis direction.

Alternatively, the separation layer forming step (S1) of the present invention may be executed by using a laser processing apparatus in which a scanning optical system that can change the direction of the laser beam LB emitted from the irradiation head 16 is disposed in the laser beam irradiation unit 6. For example, this scanning optical system includes a galvano scanner, an acousto-optic element (AOD), and/or a polygon mirror, and so forth.

That is, in the separation layer forming step (S1) of the present invention, it suffices that the ingot 11 held by the holding table 4 and the multiple focal points on each of which the laser beam LB emitted from the irradiation head 16 is focused can relatively move along each of the X-axis direction, the Y-axis direction, and the Z-axis direction, and there is no limitation on the structure for this purpose.

Moreover, the direction (first direction) along which the multiple focal points line up in the separation layer forming step (S1) of the present invention is not limited to a direction parallel to the crystal plane (10-12). That is, in the present invention, it suffices that the first direction is set to be parallel to a specific crystal plane of the single-crystal material, and the specific crystal plane can be optionally selected.

Furthermore, in the present invention, forming the separation layers 15 in the whole region of the inside of the ingot 11 in the separation layer forming step (S1) is not an indispensable characteristic. For example, in the case in which the cracks 15b extend to a region in the vicinity of the side surface 11c of the ingot 11 in the splitting-off step (S2), the separation layer 15 does not need to be formed in part or the whole of the region in the vicinity of the side surface 11c of the ingot 11 in the separation layer forming step (S1).

Moreover, the splitting-off step (S2) of the present invention may be executed by using an apparatus other than the splitting-off apparatus 18 illustrated in FIG. 10A and FIG. 10B. For example, in the splitting-off step (S2) of the present invention, the substrate 17 may be split off from the ingot 11 by sucking the side of the front surface 11a of the ingot 11.

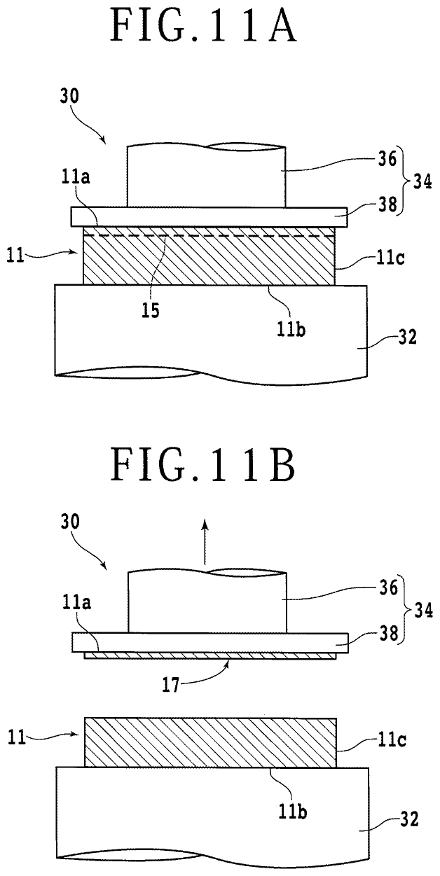

Each of FIG. 11A and FIG. 11B is a partially sectional side view schematically illustrating one example of the splitting-off step (S2) executed in this manner. A splitting-off apparatus 30 illustrated in FIG. 11A and FIG. 11B has a holding table 32 that holds the ingot 11 in which the separation layers 15 have been formed.

The holding table 32 has a circular upper surface (holding surface) and a porous plate (not illustrated) is exposed in this holding surface. Moreover, this porous plate communicates with a suction source (not illustrated) such as a vacuum pump through a flow path made inside the holding table 32, and so forth. Thus, when this suction source operates, a suction force acts on a space in the vicinity of the holding surface of the holding table 32.

Furthermore, a splitting-off unit 34 is disposed over the holding table 32. The splitting-off unit 34 has a support component 36 with a circular column shape. To an upper part of this support component 36, a raising-lowering mechanism (not illustrated) of a ball screw system is coupled, for example. The splitting-off unit 34 rises and lowers by operating this raising-lowering mechanism.

Moreover, a lower end part of the support component 36 is fixed to the center of an upper part of a suction plate 38 with a circular disc shape. Multiple suction ports are formed in the lower surface of the suction plate 38, and each of the multiple suction ports communicates with a suction source (not illustrated) such as a vacuum pump through a flow path made inside the suction plate 38, and so forth. Thus, when this suction source operates, a suction force acts on a space in the vicinity of the lower surface of the suction plate 38.

In the splitting-off apparatus 30, the splitting-off step (S2) is executed in the following order, for example. Specifically, first, the ingot 11 is placed on the holding table 32 in such a manner that the center of the back surface 11b of the ingot 11 in which the separation layers 15 have been formed is made to correspond with the center of the holding surface of the holding table 32.

Subsequently, the suction source communicating with the porous plate exposed in this holding surface is operated to cause the ingot 11 to be held by the holding table 32. Next, the raising-lowering mechanism is operated and the splitting-off unit 34 is lowered to bring the lower surface of the suction plate 38 into contact with the front surface 11a of the ingot 11.

Subsequently, the suction source communicating with the multiple suction ports formed in the suction plate 38 is operated to cause the side of the front surface 11a of the ingot 11 to be sucked through the multiple suction ports (see FIG. 11A). Next, the raising-lowering mechanism is operated and the splitting-off unit 34 is raised to separate the suction plate 38 from the holding table 32 (see FIG. 11B).

At this time, an upward force acts on the side of the front surface 11a of the ingot 11 for which the side of the front surface 11a is sucked through the multiple suction ports formed in the suction plate 38. As a result, the cracks 15b included in the respective separation layers 15 further extend to connect the adjacent separation layers 15 and the side of the front surface 11a and the side of the back surface 11b of the ingot 11 are split off. That is, the substrate 17 is manufactured from the ingot 11 with use of the separation layers 15 as the point of origin.

Furthermore, in the splitting-off step (S2) of the present invention, ultrasonic may be given to the side of the front surface 11a of the ingot 11 prior to the splitting-off between the side of the front surface 11a and the side of the back surface 11b of the ingot 11. In this case, the cracks 15b included in the respective separation layers 15 further extend to connect the adjacent separation layers 15 and therefore the splitting-off between the side of the front surface 11a and the side of the back surface 11b of the ingot 11 becomes easy.

Moreover, in the present invention, the front surface 11a of the ingot 11 may be planarized by grinding or polishing (planarization step) prior to the separation layer forming step (S1). For example, this planarization may be executed when multiple substrates are manufactured from the ingot 11.

Specifically, when splitting-off in the ingot 11 is caused at the separation layers 15 and the substrate 17 is manufactured, recesses and projections that reflect the distribution of the modified parts 15a and the cracks 15b included in the separation layers 15 are formed in the newly-exposed surface of the ingot 11. Thus, in the case of manufacturing a new substrate from the ingot 11, it is preferable to planarize the surface of the ingot 11 prior to the separation layer forming step (S1).

This can suppress diffuse reflection of the laser beam LB with which the ingot 11 is irradiated in the separation layer forming step (S1) at the surface of the ingot 11. Similarly, in the present invention, the surface on the side of the separation layers 15 in the substrate 17 split off from the ingot 11 may be planarized by grinding or polishing.

Besides, structures, methods, and so forth according to the above-described embodiment can be carried out with appropriate changes without departing from the range of the object of the present invention.

The present invention is not limited to the details of the above described preferred embodiment. The scope of the invention is defined by the appended claim and all changes and modifications as fall within the equivalence of the scope of the claim are therefore to be embraced by the invention.

What is claimed is:

1. A manufacturing method of a substrate by which the substrate is manufactured from an ingot composed of a single-crystal material, the manufacturing method comprising:
a separation layer forming step of forming separation layers including modified parts and cracks that extend from the modified parts inside the ingot by executing irradiation with a laser beam with such a wavelength as to be transmitted through the single-crystal material from a side of a front surface; and
a splitting-off step of splitting off the substrate from the ingot with use of the separation layers as a point of origin, wherein,
in the separation layer forming step, the separation layers are formed by relatively moving the ingot and a plurality of focal points along a second direction parallel to each of the front surface and a specific crystal plane of the single-crystal material in a state in which the laser beam is split in such a manner that the plurality of focal points that line up along a first direction that is non-parallel to the front surface and is parallel to the specific crystal plane are formed.
